(19) United States
(12) Patent Application Publication
(10) Pub. No.: US 2013/0277825 A1
(43) Pub. Date: Oct. 24, 2013

(54) Method for Preventing Corrosion of Copper-Aluminum Intermetallic Compounds

(71) Applicant: TEXAS INSTRUMENTS INCORPORATED, Dallas, TX (US)

(72) Inventors: Rongwei Zhang, Richardson, TX (US); Abram Castro, Fort Worth, TX (US)

(73) Assignee: TEXAS INSTRUMENTS INCORPORATED, Dallas, TX (US)

(21) Appl. No.: 13/751,663

(22) Filed: Jan. 28, 2013

Related U.S. Application Data
(60) Provisional application No. 61/635,022, filed on Apr. 18, 2012.

(51) Int. Cl. H01L 23/29; H01L 21/56

(52) U.S. Cl. CPC H01L 23/293; H01L 21/56
USPC 257/734; 438/127

(57) ABSTRACT

The packaging of an electric contact including a semiconductor chip (102) having terminals (101) of a first metal and connecting wires (111, 112) of a second metal, the wires forming at the terminals regions (113) of intermetallic compounds of the first and second metals; a solution of an aromatic azole compound dissolved in ethanol is dispensed onto the surfaces of the wire spans and the intermetallic regions, thereby forming on the surfaces layers (301) of adsorbed molecules of the aromatic azole compound; chip and wire bonds are encapsulated in a polymerizable resin (401), thereby exploiting the adsorbed aromatic azole molecules as catalysts to cross-link resin molecules into polymerized structures (402) having a mesh density capable of inhibiting the diffusion of impurity ions (410) and thus protecting the surface of the intermetallic regions.

### FIELD OF THE INVENTION

The present invention is related in general to the field of semiconductor devices and processes, and more specifically to plastic-packaged semiconductor devices with corrosion-protected copper-aluminum intermetallic compounds and methods to fabricate these protections.

### DESCRIPTION OF RELATED ART

Stimulated by the recent steep increase in the price of gold, efforts have started in the semiconductor industry to replace the traditional gold wires and gold balls by lower cost copper wires and copper balls. In addition to the cost reduction, the advantages of copper as metal for the wires include improved electrical and thermal conductivity, better mechanical properties, and higher pull strength of the attached wires. The technologies for forming free air balls from copper wires and forming copper-to-aluminum intermetallics after the copper ball touch-down on the aluminum pads have been solved to a great extent. The dominant intermetallic compounds are CuAl₂ on the side of the aluminum pad, and Cu₉Al₄ on the side of the copper ball; with enough temperature and annealing time, CuAl can form between them. The intermetallic compounds are mixed in a layer between the aluminum pad and the copper ball.

Recent studies by moisture tests of the reliability of plastic packaged devices with copper/aluminum contacts have shown that especially the copper-aluminum intermetallic compounds are susceptible to corrosion. In the standardized reliability tests of electronic devices, statistical amounts of wire bonds are tested in moisture-free (dry) ambient and compared to statistical amounts of wire bonds in moist ambient. The moisture tests look for failures caused by corroded metals, weakened contacts, leakage and delamination of device packages, and degraded electrical characteristics under functional operation.

In the so-called THB test, the bonded units are subjected to 85% relative humidity at 85° C. under electrical bias for at least 600 hours, preferably 100 hours. In the so-called HAST test, the bonded units are subjected to 85% relative humidity at either 110° C. for 264 h or 130° C. for 96 h, preferably 192 h, under electrical bias. In the pressure test, the bonded units are subjected to 100% relative humidity at 121° C., unbiased, for at least 96 hours, preferably 240 hours. In these tests, the magnitude of the electrical bias is determined by the device type, and the number of allowed failures by standardized wire pull and ball shear tests is determined by the customer for the intended application such as automotive application. The results showed that copper wire bonds to aluminum pads deliver strong mechanical performance in dry tests but failed HAST at high rates (between 12 and 99%). All malfunctioning units failed by cracking through the interface between the copper ball and the aluminum pad.

In many cases, the corrosion-induced failure is associated with ionic impurity, especially chloride ions in molding compounds. Chloride ions act as catalyst for corrosion and will not be consumed after the reaction, even though the amount may be less than 20 ppm. Reducing the amount of hydrogen and chloride ions in molding compounds has been proved to enhance the reliability of copper wire bonds on aluminum pads. Ion catchers are typically incorporated into molding compounds to decrease the amount of mobile chloride ions. It has been found, however, that a high ion catcher concentration will absorb wax, which can affect the moldability of molding compounds. Ion catchers contain water, which may cause curability degradation. Moreover, many ion catchers are based on ion exchange mechanisms so that an ion catcher may absorb chloride ions, but release other ions such as hydroxyl ions, which may also cause corrosion.

Purified resins have been introduced, but cause unwelcome cost increases. Replacing copper wires by palladium-coated copper wires produced better reliability than bare copper wires in terms of intermetallic corrosion, but improvements are limited as the distribution of palladium at the interface cannot be well controlled. Moreover, cost will significantly increase.

### SUMMARY OF THE INVENTION

Applicants realized that for the application of copper wires in wire-bonded plastic-encapsulated devices, main attention needs to be paid to keeping away ionic impurities from the copper-aluminum intermetallic (IMC) region in order to prevent IMC corrosion. A solution was advanced when applicants discovered a method to encapsulate the intermetallic region in a polymerized barrier layer with a mesh density capable of inhibiting the diffusion of impurity ions.

In applicants' barrier layer method, the surface of the intermetallic region is first covered with an adsorbed layer of corrosion inhibitor such as benzotriasole (BTA). Then the catalytic capability of the inhibitor (for example BTA) is exploited to polymerize epoxy-type molecules of the molding compound into a dense mesh of polymerized structures surrounding the intermetallic region; at the same time, the inhibitor covalently bonds to the polymer network. The result is a zone contiguous with the surface of the intermetallic compounds, in which the polymerized molecules are structured in a mesh density capable of restraining the diffusion of impurity ions, thus preventing the corrosion of intermetallic compounds. The ions include especially the negatively charged ions of the halides (fluorine, chlorine, bromine) and certain acids (sulfuric acid, phosphoric acid, nitric acid).

The corrosion inhibitor is preferably selected from a group of aromatic azoles including 1,2,3-benzotriazole (C₆H₅N₃) and its 5-alkyl-derivatives of methyl-benzotriazole, butyl-benzotriazole, hexyl-benzotriazole, octyl-benzotriazole, and dodecyl-benzotriazole. The aromatic azole is dissolved in ethanol and the solution dispensed onto the surfaces of freshly formed ball and stitch bonds and wire spans of wire bonded devices. The molecules of the aromatic azole are adsorbed on the intermetallic and wire surfaces, while the ethanol evaporates after dispensing.

Benzotriazole (BTA) and its derivatives have been proved to be effective to prevent the corrosion of copper and copper-aluminum intermetallics due to the adsorption of BTA molecules on the copper and intermetallic surfaces and the formation of a layer of protective complex with copper. As an additional characteristic in plastic encapsulated devices, the catalytic property of BTA and other corrosion inhibitors (heterocyclic compound such as 4,5-diamino-2,6-dimercaptopyrimidine) are exploited as coupling agents to polymerize epoxy-type molecules of molding compounds into structures with a mesh density capable of restraining the diffusion of impurity ions towards the copper and intermetallic surfaces.

It is a technical advantage of the invention that the method for forming high density polymerized regions covering the wire and intermetallic surfaces and preventing intermetallic corrosion does not require additional time, equipment or expenditure compared to conventional wire bonding and encapsulation processes.

It is another technical advantage that the method of the invention can be implemented in any packaging process flow of any semiconductor device using wire bonding and plastic encapsulation.

It is another technical advantage that the compounds adsorbed on the wire surfaces are not only effective as corrosion inhibitors and polymerization catalysts, but also as compounds improving the adhesion between encapsulation compounds and copper wires.

### BRIEF DESCRIPTION OF THE DRAWINGS

FIG. 1 illustrates a wire ball-bond to a metallic pad, whereby an intermetallic layer is formed, over which a solution of an aromatic azole compound dissolved in ethanol is dispensed.

FIG. 2 depicts the chemical representation of an aromatic azole molecule and the adsorption of dispensed aromatic azole molecules on the surface of copper and the intermetallic layer.

FIG. 3 shows a layer of adsorbed aromatic azole molecules on the surface of a metal wire bond with intermetallic layer before encapsulating the bond.

FIG. 4 depicts a layer of adsorbed aromatic azole molecules on the surface of a metal wire bond with intermetallic layer after encapsulating the bond in a polymeric packaging compound, together with an enlargement of a portion of the polymeric compound contiguous with the metal surface, including the region of polymerized molecules structured in a mesh density capable of inhibiting the diffusion of impurity ions.

### DETAILED DESCRIPTION OF THE PREFERRED EMBODIMENTS

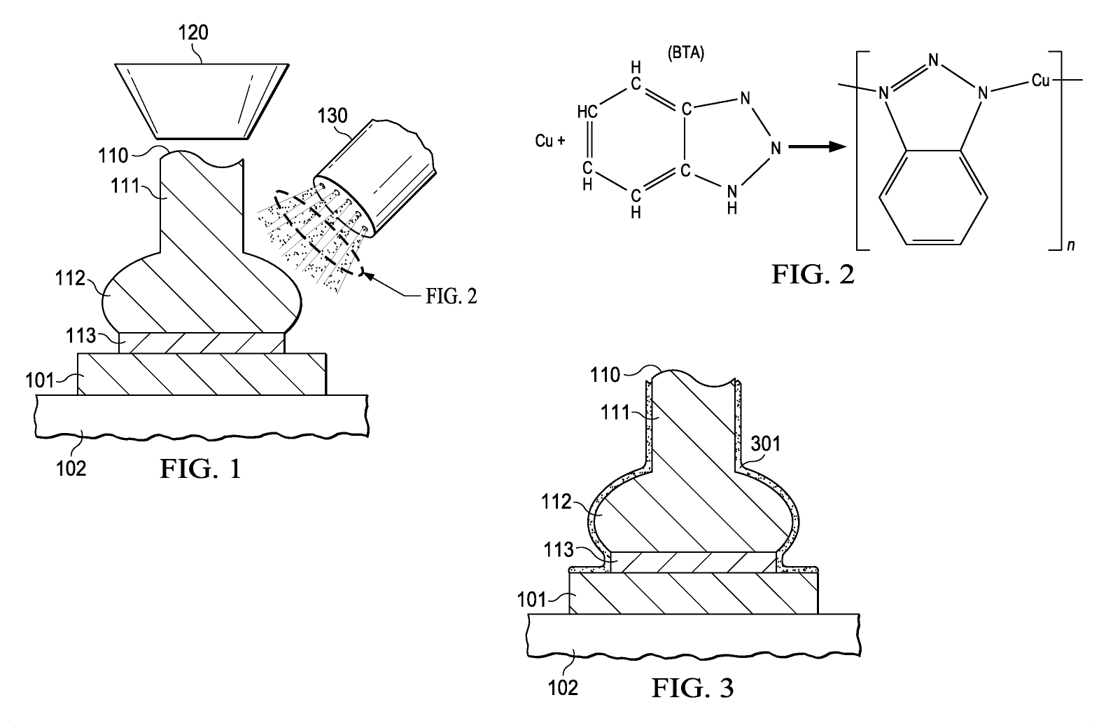

The exemplary embodiment illustrated in FIG. 1 displays schematically a terminal pad 101 of a semiconductor chip 102 contacted by a connecting wire 110. Terminal pad 101 is made of aluminum, often alloyed with 0.5 to 2% copper and/or 0.5 to 1% silicon. The pad is about 0.4 to 1.5 μm thick. Under the aluminum (not shown in FIG. 1) is frequently a thin layer (4 to 20 nm thick) of titanium, titanium nitride, titanium tungsten, tantalum, tantalum nitride, tantalum silicon nitride, tungsten nitride, or tungsten silicon nitride.

In FIG. 1, the connecting wire 110 includes a portion 111 of the round wire with a first diameter between about 15 to 33 μm, preferably 20 to 25 μm, and an end portion 112 with a second diameter greater than the first diameter. Due to its shape, the end portion 112 is often referred to as the wire nail head or the squashed wire sphere or ball. The wire consists of copper. Wire 110 has been delivered, and squashed ball 112 has been formed and attached by capillary 120.

The wire bonding process begins by positioning the semiconductor chip 102 with the aluminum pad 101 on a heated pedestal to raise the temperature to between 150 and 300° C. Ball formation and bonding need to be performed in a reducing atmosphere, preferably including dry nitrogen gas with a few percent hydrogen gas. The wire 110 is strung through a capillary 120. At the tip of the wire of first diameter, a wire end of second diameter greater than the first diameter, usually a free air ball is created using either a flame or a spark technique. The ball has a typical diameter from about 1.2 to 1.6 wire diameters. The capillary is moved towards the chip bonding pad 101 and the ball is pressed against the metallization of the pad. For pads of aluminum, a combination of compression force and ultrasonic energy creates the progressing formation of copper-aluminum intermetallics 113 and thus a strong metallurgical bond. The compression (also called Z— or mash) force is typically between about 17 and 75 gram-force/cm² (about 1670 to 7355 Pa); the ultrasonic time between about 10 and 30 ms; the ultrasonic power between about 20 and 50 mW. At time of bonding, the temperature usually ranges from 150 to 300° C. The bonding process results in the copper nail head or squashed ball 112 illustrated in FIG. 1.

At the beginning of the bonding process, the copper free air ball is brought to contact with the aluminum pad 101. The surfaces of the copper ball and the aluminum substrate 101 are free of contaminants such as oxides, insulating layers, and particulate impurities. The contact between copper ball and aluminum pad is achieved while the copper ball is under pressure and while energy is applied to the contact; one portion of the energy is thermal, provided by the elevating the temperature 150 to 300° C., and the other portion is ultrasonic energy, provided by the ultrasonic movement of the copper ball relative to the aluminum pad.

After a period of time (between about 10 and 20 ms) since turning-on the ultrasonic movement, thermal and ultrasonic energy have caused the interdiffusion of copper and aluminum atoms at the interface to create a layer 113 of intermetallic compounds in the thickness range from about 50 to 100 nm. While six copper/aluminum intermetallic compounds are known, the dominant compounds include CuAl₂ at the side of the aluminum pad 101, and Cu₉Al₄ at the side of the copper ball 112; in addition, CuAl is formed between these compounds when the time span of ultrasonic agitation is sufficiently long. As indicated in FIG. 1, layer 113 of copper/aluminum intermetallic compounds has a small surface portion exposed to the ambient.

After completing the wire-bonding operation, automated bonders (for example available from the company Kulicke & Soffa, Fort Washington, Pa.) offer on-bonder dispense systems with a nozzle 130, which allow the dispensing of liquids over the just-completed wire spans (including wire, ball, stitch). An exemplary liquid consists of a solution of about 1 milli-mole per liter (mmol/L) of a corrosion inhibitor such as benzotriazole (BTA) or its derivatives in ethanol. Alternatively, a solution in ethanol with corrosion inhibitors such as 4,5-diamino-2,6-dimercaptopyrimidine may be used. In the dispensing step, a layer of liquid is formed on the wire surfaces. BTA molecules are adsorbed on the copper surface, forming a protective complex with copper, and the ethanol will be evaporated after dispensing, while at least one monolayer of the corrosion inhibitor compound remains adsorbed on the wire surfaces.

By way of explanation with regard to BTA, 1,2,3-benzotriazole BTA is the organic compound C₆H₅N₃ consisting of a benzene ring combined with a triazole ring (being a five-membered ring compound with three nitrogens in the ring). The molecular structure of BTA and the molecular position when adsorbed on the copper surface are depicted in FIG. 2. The presence of nitrogen atoms in the triazole ring enables bonding with copper (complex Cu(I)BTA) and is a basis for the inhibiting effect of BTA. BTA molecules can be oriented parallel or vertical to the surface. Besides 1,2,3-benzotriazole, its 5-alkyl-derivatives: methyl-benzotriazole, butyl-benzotriazole, hexyl-benzotriazole, octyl-benzotriazole, and dodecyl-benzotriazole, can be used.

By way of explanation with regards to 4,5-diamino-2,6-dimercaptopyrimidine, in mercaptan compounds, an OH group of an alcohol is substituted by an SH group. Pyrimidine is a heterocyclic compound with the formula C₄H₄N₂; in a benzene ring, two nitrogen atoms are replacing two CH groups. When adsorbed on the copper surface, diaminodimercaptopyrimidine acts as a corrosion inhibitor and as a coupling agent to polymerize molecules of the molding resin into a densely meshed polymer network. The stability of corrosion inhibitor is combined with effective protection of the intermetallic compound, and with adhesion between molding compound and wire bonds.

In FIG. 3, designation 301 indicates the adsorbed at least one monolayer of molecules of an aromatic azole compound, or heterocyclic compound on the surfaces of the copper wire, squashed copper ball, and copper/aluminum intermetallic compounds. In this configuration, the wire-bonded semiconductor assembly is subjected to an encapsulation process with a polymerizable resin. The preferred method is a transfer molding process with an epoxy-type resin.

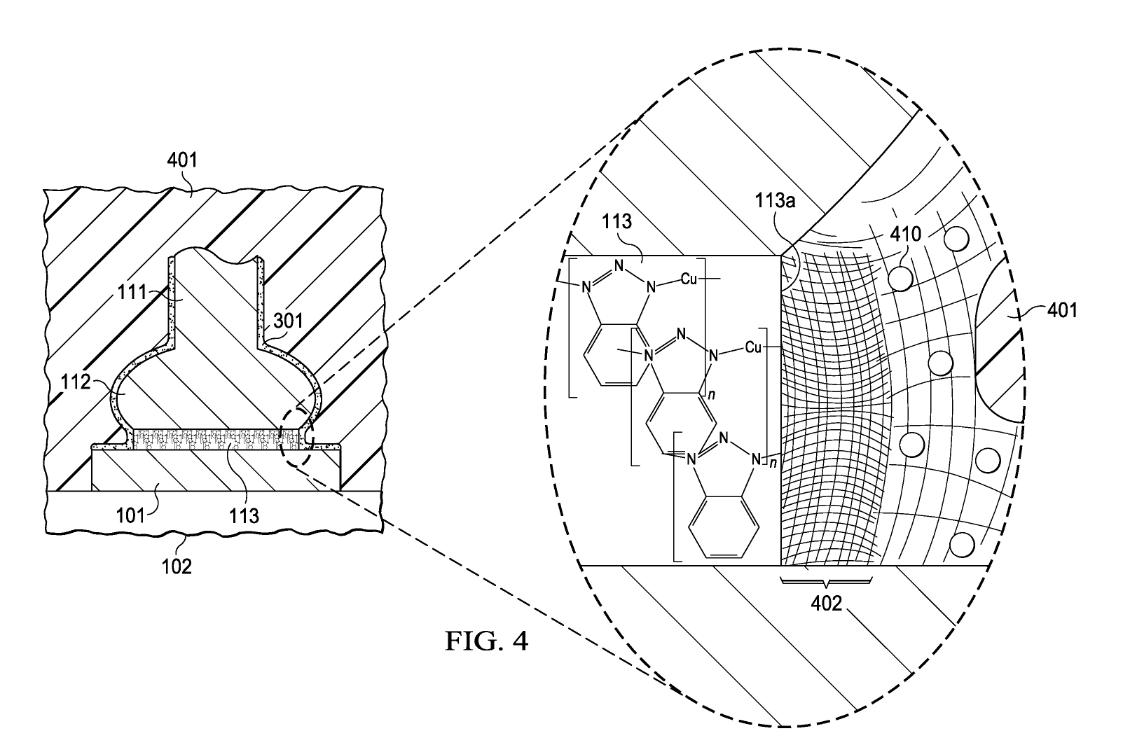

In FIG. 4, the assembly including a wire (111 and 112) of a second metal bonded to a chip terminal 101 of a first metal, further a region 113 of intermetallic compounds between the first and second metals, and a layer 301 of an azole compound adsorbed on the intermetallic surface 113a, is encapsulated in a package of polymeric resin 401. The resin includes a zone 402 contiguous with the surface 113a of the intermetallic compounds, in which the polymerized molecules are structured in a mesh density capable of restraining the diffusion of impurity ions. In FIG. 4, some ions are schematically indicated by circles 410. Among the hindered impurity ions are especially the ions of halide elements (fluorine, chlorine, and bromine) and the ions of acids such as sulfuric acid, phosphoric acid, and nitric acid (sulfate, phosphate, and nitrate). Ions with one or more negative charges are known to exhibit especially large sizes.

Zone 402 of polymerized resin molecules with high mesh density is created by the catalytic properties of the adsorbed inhibitor molecules of azole or diaminodimercaptopyrimidine compound families. These catalytic properties polymerize resin molecules of the molding compounds at the copper and intermetallic surfaces. The covalent bond of the inhibitor molecules to the dense polymer network will be further strengthened during the time and elevated temperatures needed for curing the molding compounds.

It is a technical advantage that protecting intermetallic compounds against ingress and attack by corrosive ions can be accomplished by a thin region 420 (<1 μm thickness) so that no adverse mechanical effect is created such as a mismatch of the coefficients of thermal expansion (CTE) on the reliability of the copper ball 112 bonded onto the aluminum pad 101.

It is another technical advantage that the polymeric nature of the protective mesh enables effective protection even at high temperatures during device operation. In addition, the adhesion between molding compounds and wire bonds is fortified, thus lowering the risk of delamination of the plastic package from the copper wires.

In contrast to the proposal of employing palladium-coated copper wires as protection against intermetallic corrosion, the described method of adsorbing a layer of aromatic azole compound for catalyzing dense resin polymerization requires no change of the wire bonding process and does not add another metal to the intermetallic compounds. Furthermore, the azole method is low cost.

Another embodiment of the present invention is a method for fabricating a plastic-packaged semiconductor device. The method uses a semiconductor chip with terminals of a first metal, preferably aluminum. In a bonding step, preferably automated ball bonding using ultrasonic agitation, the terminals are connected to a substrate with wires made of a second metal, preferably copper. Alternatively, the second metal may be gold, aluminum, and alloys thereof. In the bonding process, intermetallic compounds between the first and the second metal are formed at the ball-to-terminal interface. For copper and aluminum, the dominant compounds include CuAl₂ at the side of the aluminum pad, and Cu₉Al₄ at the side of the copper ball; in addition, CuAl is formed between these compounds when the time span of ultrasonic agitation is sufficiently long.

In conjunction with the automated bonders, a solution of an aromatic azole compound dissolved in ethanol is dispensed onto the surfaces of the wire spans and the intermetallic regions, thereby forming on the surfaces layers of adsorbed molecules of the aromatic azole compound. A preferred azole compound is benzotriazole; alternatively, its 5-alkyl-derivatives: methyl-benzotriazole, butyl-benzotriazole, hexyl-benzotriazole, octyl-benzotriazole, and dodecyl-benzotriazole, can be used. In still another alternative, a solution in ethanol with a corrosion inhibitor such as 4,5-diamino-2,6-dimercaptopyrimidine may be used.

In the next process step, the chip and the connecting wires are encapsulated in a polymerizable resin, preferably an epoxy-based resin in molding compounds. The molding compounds may further include inorganic fillers such as silicon dioxide and silicon carbide, curing agents selected from an amine, acrid anhydrates, and phenol. In this process step, the adsorbed aromatic azole molecules are exploited as catalysts to cross-link resin molecules into polymerized structures having a mesh density capable of inhibiting the diffusion of impurity ions and thus protecting the surface of the intermetallic regions. For plastic packaged semiconductor devices, many of these ions may originate in the plastic resin or the fillers, such as ions of chloride and fluoride. Other inhibited impurities include ions of sodium, ammonium, potassium, hydroxide, nitrate, sulfate, phosphate, and related compounds.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the invention applies to products using any type of wire-bonded semiconductor chip, discrete or integrated circuit, and the material of the semiconductor chip may comprise silicon, silicon germanium, gallium arsenide, or any other semiconductor or compound material used in integrated circuit manufacturing.

As another example, the invention applies to systems including a plurality of electronic components with interconnecting copper wires bonded to aluminum contact pads, which are at risk of being corroded at their intermetallic interfaces. These systems may be used many applications such as automotive, portable and hand-held applications. In yet another example, the invention applies to any system where intermetallic compounds between copper and aluminum can be found.

It is therefore intended that the appended claims encompass any such modifications or embodiment.

We claim:

1. A semiconductor device comprising:
a semiconductor chip having terminals of a first metal;
the terminals connected to a substrate by a wire of a second metal, the wires forming, at the terminals, regions of intermetallic compounds of the first and second metals;
the surfaces of the wires and the intermetallic regions having a layer of adsorbed molecules of an aromatic azole compound; and
the chip and the wires encapsulated in a package of polymeric resin including a zone contiguous with the surface of the intermetallic compounds, wherein the polymerized molecules are structured in a mesh density capable of inhibiting the diffusion of impurity ions.

2. The device of claim 1 wherein the first metal is aluminum.

3. The device of claim 1 wherein the second metal is selected from a group including copper, gold, aluminum, and alloys thereof.

4. The device of claim 1 wherein the aromatic azole compound is selected from a group including 1,2,3-benzotriazole (C₆H₅N₃) and its 5-alkyl-derivatives of methyl-benzotriazole, butyl-benzotriazole, hexyl-benzotriazole, octyl-benzotriazole, and dodecyl-benzotriazole.

5. The device of claim 1 wherein the polymerizable resin is an epoxy resin.

6. The device of claim 1 wherein the impurity ions include chloride, fluoride, bromide, sodium, ammonium, potassium, hydroxide, sulfate, phosphate, nitrate, and other related ions.

7. A method for fabricating a packaged semiconductor device comprising the steps of:
providing a semiconductor chip having terminals of a first metal;
connecting the terminals to a substrate by spanning wires of a second metal, the wires forming at the terminals regions of intermetallic compounds of the first and second metals;
dispensing a solution of an aromatic azole compound dissolved in ethanol onto the surfaces of the wire spans and the intermetallic regions, thereby forming on the surfaces layers of adsorbed molecules of the aromatic azole compound; and
encapsulating the chip and the wire spans in a polymerizable resin in molding compounds, thereby exploiting the adsorbed aromatic azole molecules as catalysts to cross-link resin molecules into polymerized structures having a mesh density capable of inhibiting the diffusion of impurity ions and thus protecting the surface of the intermetallic regions.

8. The method of claim 7 wherein the first metal is aluminum.

9. The method of claim 7 wherein the second metal is selected from a group including copper, gold, aluminum, and alloys thereof.

10. The method of claim 7 wherein the aromatic azole compound is selected from a group including 1,2,3-benzotriazole (C₆H₅N₃) and its 5-alkyl-derivatives of methyl-benzotriazole, butyl-benzotriazole, hexyl-benzotriazole, octyl-benzotriazole, and dodecyl-benzotriazole.

11. The method of claim 7 wherein the polymerizable resin is an epoxy resin.

12. The method of claim 11 wherein the polymerizable resin further includes a curing agent selected from a group including amines, acid anhydrates, and phenol.

13. The method of claim 7 wherein the impurity ions include fluoride, chloride, bromide, sodium, ammonium, potassium, hydroxide, sulfate, phosphate, nitrate, and other ions present in the system.
